(19) United States
(12) Patent Application Publication
(10) Pub. No.: US 2024/0215400 A1
(43) Pub. Date: Jun. 27, 2024

(54) DISPLAY APPARATUS AND METHOD OF MANUFACTURING THE SAME

(71) Applicant: Samsung Display Co., LTD., Yongin-si (KR)

(72) Inventors: Dongkyun SEO, Yongin-si (KR); Youngjun KIM, Yongin-si (KR); Hyunyoung JUNG, Yongin-si (KR); Seonhwa CHOI, Yongin-si (KR)

(21) Appl. No.: 18/393,953

(22) Filed: Dec. 22, 2023

(30) Foreign Application Priority Data
Dec. 23, 2022 (KR) 10-2022-0183493

(51) Int. Cl. H10K 59/80; H10K 71/15

(52) U.S. Cl. CPC H10K 59/875; H10K 71/15

(57) ABSTRACT

A display apparatus including a first base layer including a first auxiliary base layer and a second auxiliary base layer disposed on the first auxiliary base layer; and a semiconductor layer dispose on the first base layer. Polyimide of the first auxiliary base layer is arranged in a preset orientation, and polyimide of the second auxiliary base layer is arranged in an arbitrary orientation.

This application claims priority to Korean Patent Application No. 10-2022-0183493, filed on Dec. 23, 2022, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the display apparatus, and more particularly, to a display apparatus with improved reliability and a method of manufacturing the display apparatus.

### 2. Description of the Related Art

A display apparatus visually displays data. A display apparatus is used as a display unit of miniaturized products such as mobile phones, and used as a display unit of large-scale products such as televisions.

The display apparatus may include liquid crystal display apparatuses that use light from a backlight without spontaneously emitting light, or light-emitting display apparatuses including a display element capable of emitting light, where the display element may include an emission layer.

### SUMMARY

One or more embodiments include a display apparatus with improved visibility and a method of manufacturing the display apparatus. However, such a technical problem is an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a first base layer including a first auxiliary base layer and a second auxiliary base layer disposed on the first auxiliary base layer; and a semiconductor layer dispose on the first base layer, where polyimide of the first auxiliary base layer is arranged in a preset orientation, and polyimide of the second auxiliary base layer is arranged in an arbitrary orientation.

The first base layer may further include a third auxiliary base layer between the first auxiliary base layer and second auxiliary base layer, and orientation of polyimide of the third auxiliary base layer may be gradually changed from the preset orientation to the arbitrary orientation in a direction from the first auxiliary base layer to the second auxiliary base layer.

The first auxiliary base layer may have a first density, and the second auxiliary base layer may have a second density less than the first density.

The first auxiliary base layer may have a first thermal expansion coefficient, and the second auxiliary base layer may have a second thermal expansion coefficient greater than the first thermal expansion coefficient.

The display apparatus may further include: a first barrier layer disposed under the first base layer, a second base layer disposed under the first barrier layer, a second barrier layer disposed on the first base layer, and a buffer layer disposed on the second barrier layer.

According to one or more embodiments, a method of manufacturing a display apparatus includes forming a first base layer and a first barrier layer on a carrier substrate, coating, on the first barrier layer, a material for forming a second base layer, where the material for forming the second base layer includes polyacrylic acid and a solvent, drying the solvent included in the material for forming the second base layer, performing first curing of a surface of the material for forming the second base layer, and performing second curing of the material for forming the second base layer, to form the second base layer including a first auxiliary base layer and a second auxiliary base layer disposed on the first auxiliary base layer, where the drying of the solvent included in the material for forming the second base layer, and the first curing of the surface of the material for forming the second base layer are performed simultaneously, the second curing is performed after the first curing, the first auxiliary base layer has a first density, and the second auxiliary base layer has a second density less than the first density.

The first auxiliary base layer and the second auxiliary base layer may include polyimide, the polyimide of the first auxiliary base layer may be arranged in a preset orientation, and the polyimide of the second auxiliary base layer may be arranged in an arbitrary orientation.

The second curing of the material for forming the second base layer to form the second base layer including the first auxiliary base layer and the second auxiliary base layer disposed on the first auxiliary base layer may include: curing a first portion of the material for forming the second base layer to form the first auxiliary base layer, where the first portion may be apart from a top surface of the material for forming the second base layer, and curing a second portion of the material for forming the second base layer adjacent to the top surface of the material for forming the second base layer, to form the second auxiliary base layer.

In the second curing of the material for forming the second base layer to form the second base layer including the first auxiliary base layer and the second auxiliary base layer disposed on the first auxiliary base layer, polyacrylic acid of the material for forming the second base layer may be imidized to form polyimide.

The solvent may include methylpyrrolidone (NMP, N-methyl-2-pyrrolidone).

A temperature of a process in which the drying of the solvent included in the material for forming the second base layer and the first curing are performed may be 50° C. or more and 90° C. or less.

A temperature of a process in which the second curing is performed may be 450° C. or more and 470° C. or less.

According to one or more embodiments, a method of manufacturing a display apparatus includes forming a first base layer and a first barrier layer on a carrier substrate, coating, on the first barrier layer, a material for forming a first auxiliary base layer, where the material for forming the first auxiliary base layer includes polyacrylic acid and a first solvent, drying the first solvent of the material for forming the first auxiliary base layer, performing first auxiliary curing of the material for forming the first auxiliary base layer to form the first auxiliary base layer, coating, on the first auxiliary base layer, a material for forming a second auxiliary base layer, where the material for forming the second auxiliary base layer includes polyacrylic acid and a second solvent, drying the second solvent of the material for forming the second auxiliary base layer, and performing second auxiliary curing of the material for forming the second auxiliary base layer to form the second auxiliary base layer, where a second base layer includes the first auxiliary base layer and the second auxiliary base layer disposed on the first auxiliary base layer, the first auxiliary base layer has a first density, and the second auxiliary base layer has a second density less than the first density.

The first auxiliary base layer and the second auxiliary base layer may include polyimide, the polyimide of the first auxiliary base layer may be arranged in a preset orientation, and the polyimide of the second auxiliary base layer may be arranged in an arbitrary orientation.

A temperature of a process in which the drying of the solvent included in the material for forming the first auxiliary base layer is performed may be 70° C. or more and 90° C. or less.

A temperature of a process in which the drying of the solvent included in the material for forming the second auxiliary base layer is performed may be 30° C. or more and 50° C. or less.

The first auxiliary curing of the material may have a first auxiliary curing speed, and the second auxiliary curing of the material may have a second auxiliary curing speed, and the second auxiliary curing speed may be greater than the first auxiliary curing speed.

A temperature of the first auxiliary curing of the material and the second auxiliary curing of the material may be 450° C. or more and 470° C. or less.

The first solvent and the second solvent may each include methylpyrrolidone (NMP, N-methyl-2-pyrrolidone).

In the first auxiliary curing of the material and the second auxiliary curing of the material, polyacrylic acid of the material for forming the first auxiliary base layer and the material for forming the second auxiliary base layer may be imidized to form polyimide.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic plan view of a display apparatus according to an embodiment;

FIGS. 3 and 4 are equivalent circuit diagrams of a pixel of a display apparatus according to an embodiment;

FIGS. 5A to 5C are schematic cross-sectional views of a display apparatus according to an embodiment;

FIGS. 6 to 8 are schematic cross-sectional views showing a method of manufacturing a display apparatus according to an embodiment; and

FIGS. 9 to 14 are schematic cross-sectional views showing a method of manufacturing a display apparatus according to an embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, where like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

It will be understood that when a layer, region, or element is referred to as being “connected” to another layer, region, or element, it may be “directly connected” to the other layer, region, or element or may be “indirectly connected” to the other layer, region, or element with other layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to other layer, region, or element t with other layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

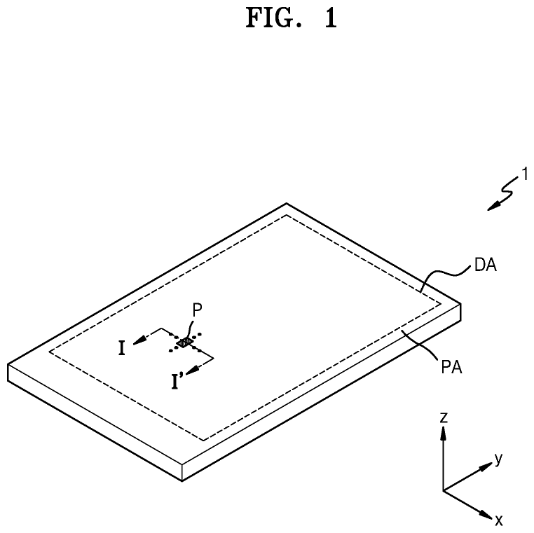

FIG. 1 is a schematic perspective view of a display apparatus 1 according to an embodiment.

Referring to FIG. 1, the display apparatus 1 may include a display area DA and a peripheral area PA outside the display area DA. The peripheral area PA may surround the display area DA. The display apparatus 1 may be configured to display images using light emitted from pixels P arranged in the display area DA, and the peripheral area PA may be a region in which images are not displayed.

Hereinafter, though an organic light-emitting display apparatus is described as an example of the display apparatus 1 according to an embodiment, the display apparatus is not limited thereto. In an embodiment, the display apparatus 1 may be an inorganic light-emitting display apparatus or a quantum-dot light-emitting display apparatus. As an example, an emission layer of a display element provided to the display apparatus 1 may include an organic material, an inorganic material, quantum dots, an organic material and quantum dots, or an inorganic material and quantum dots.

Although FIG. 1 shows the display apparatus 1 including a flat display surface, the embodiment is not limited thereto. In an embodiment, the display apparatus 1 may include a three-dimensional display surface or a curved display surface.

FIG. 1 shows the display apparatus 1 applicable to a mobile phone terminal. Though not shown, an electronic module, a camera module, a power module, and the like mounted on a mainboard may be disposed in a bracket/case and the like together with the display apparatus 1 to configure a mobile phone terminal. Particularly, the display apparatus 1 is applicable to large-sized electronic apparatuses such as televisions and monitors and small and medium-sized electronic apparatuses such as tablets, car navigation apparatuses, game consoles, and smartwatches.

Though it is shown in FIG. 1 that the display area DA of the display apparatus 1 is quadrangular, the shape of the display area DA may be circular, elliptical, or polygons such as triangles or pentagons.

The display apparatus 1 may include the pixels P arranged in the display area DA. Each of the pixels P may include an organic light-emitting diode OLED. Each pixel P may be configured to emit, for example, red, green, blue, or white light from the organic light-emitting diode OLED. As described above, the pixel P may be understood as a pixel that is configured to emit light having one of red, green, blue, and white.

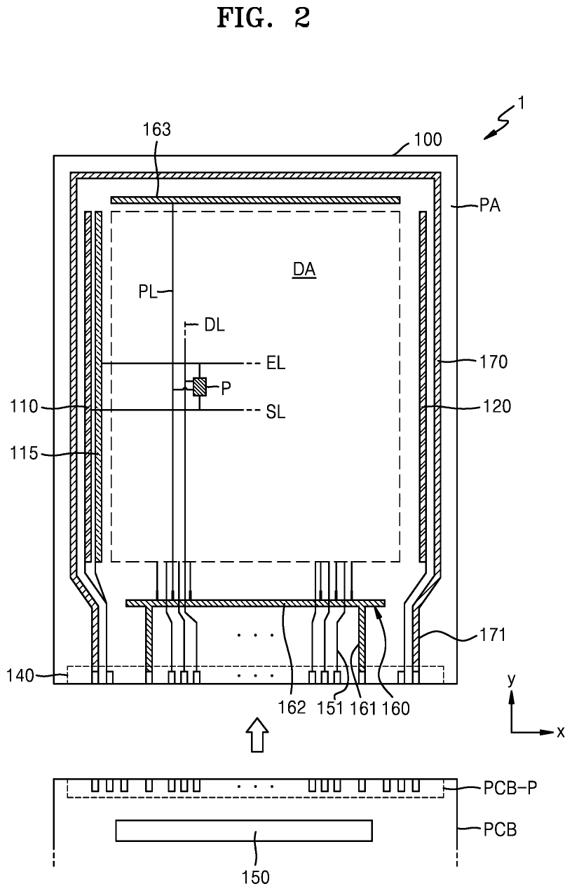

FIG. 2 is a schematic plan view of the display apparatus 1 according to an embodiment.

Referring to FIG. 2, the display apparatus 1 includes the pixels P arranged in the display area DA. Each pixel P may be electrically connected to outer circuits arranged in the peripheral area PA. A first scan driving circuit 110, a first emission driving circuit 115, a second scan driving circuit 120, a terminal 140, a data driving circuit 150, a first power supply line 160, and a second power supply line 170 may be arranged in the peripheral area PA.

The first scan driving circuit 110 may be configured to provide scan signals to each pixel P through a scan line SL. The first emission driving circuit 115 may be configured to provide emission control signals to each pixel P through an emission control line EL. The second scan driving circuit 120 may be arranged in parallel to the first scan driving circuit 110 with the display area DA therebetween. In an embodiment, some of the pixels P arranged in the display area DA may be electrically connected to the first scan driving circuit 110, and the rest of the pixels P may be electrically connected to the second scan driving circuit 120. In an embodiment, the second scan driving circuit 120 may be omitted.

The first emission driving circuit 115 may be apart in an x direction from the first scan driving circuit 110 in the peripheral area PA. In addition, the first emission driving circuit 115 may be alternately arranged with the first scan driving circuit 110 in a y direction.

The terminal 140 may be arranged on one side of a substrate 100. The terminal 140 may be exposed by not being covered by an insulating layer, and electrically connected to a printed circuit board PCB. A terminal PCB-P of the printed circuit board PCB may be electrically connected to the terminal 140 of the display apparatus 1. The printed circuit board PCB is configured to transfer signals of a controller (not shown) or power to the display apparatus 1. Control signals generated by the controller may be respectively transferred to the first scan driving circuit 110, the first emission driving circuit 115, and the second scan driving circuit 120 through the printed circuit board PCB. The controller may be configured to respectively provide a first power voltage ELVDD (a driving voltage) and a second power voltage ELVSS (a common voltage) to the first power supply line 160 and the second power supply line 170 through a first connection line 161 and a second connection line 171. The first power voltage ELVDD may be provided to a driving voltage line PL connected to the first power supply line 160, and the second power voltage ELVSS may be provided to an opposite electrode of each pixel P, connected to the second power supply line 170.

The data driving circuit 150 may be electrically connected to a data line DL. A data signal of the data driving circuit 150 may be provided to each pixel P through a connection line 151 and the data line DL, where the connection line 151 is connected to the terminal 140, and the data line DL is connected to the connection line 151.

Although it is shown in FIG. 2 that the data driving circuit 150 is disposed on the printed circuit board PCB, the data driving circuit 150 may be disposed on the substrate 100 in an embodiment. As an example, the data driving circuit 150 may be arranged between the terminal 140 and the first power supply line 160.

The first power supply line 160 may include a first sub-line 162 and a second sub-line 163 extending in parallel to each other in the x direction with the display area DA therebetween. The second power supply line 170 may have a loop shape having one open side to partially surround the display area DA.

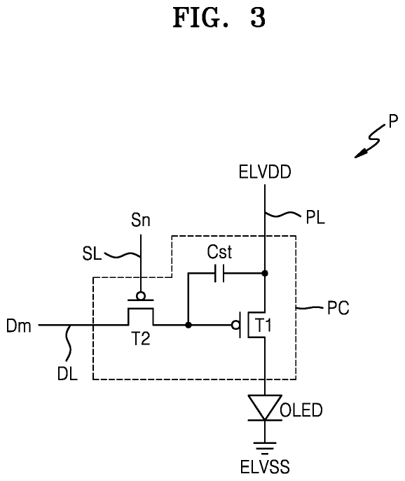

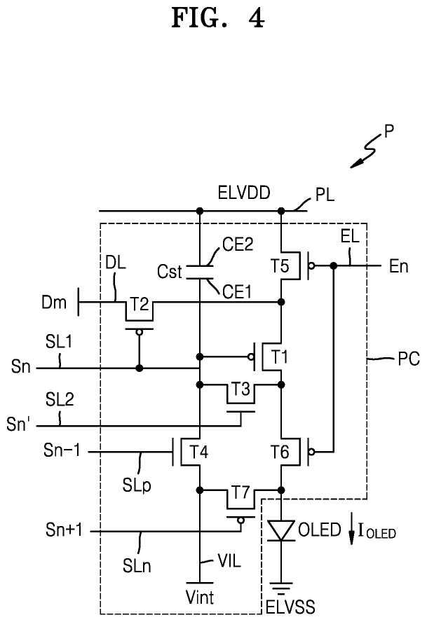

FIGS. 3 and 4 are equivalent circuit diagrams of a pixel of the display apparatus 1 according to an embodiment.

Referring to FIG. 3, each pixel P may include a pixel circuit PC and the organic light-emitting diode OLED connected to the pixel circuit PC, where the pixel circuit PC is connected to the scan line SL and the data line DL.

The pixel circuit PC may include a driving thin-film transistor T1, a switching thin-film transistor T2, and a storage capacitor Cst. The switching thin-film transistor T2 may be connected to the scan line SL and the data line DL, and configured to transfer a data signal Dm to the driving thin-film transistor T1 according to a scan signal Sn, where the data signal Dm is input through the data line DL, and the scan signal Sn is input through the scan line SL.

The storage capacitor Cst may be connected to the switching thin-film transistor T2 and the driving voltage line PL and configured to store a voltage corresponding to a difference between a voltage transferred from the switching thin-film transistor T2 and the driving voltage ELVDD supplied to the driving voltage line PL.

The driving thin-film transistor T1 may be connected to the driving voltage line PL and the storage capacitor Cst and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current.

Although it is described with reference to FIG. 3 that the pixel circuit PC includes two thin-film transistors and one storage capacitor, the embodiment is not limited thereto. As an example, the pixel circuit PC may include three or more thin-film transistors and/or two or more storage capacitors. In an embodiment, the pixel circuit PC may include seven thin-film transistors and one storage capacitor. Alternatively, the pixel circuit PC may include seven thin-film transistors and two storage capacitors.

Referring to FIG. 4, a pixel P may include the pixel circuit PC and the organic light-emitting diode OLED electrically connected to the pixel circuit PC.

In an embodiment, as shown in FIG. 4, the pixel circuit PC may include a plurality of thin-film transistors T1, T2, T3, T4, T5, T6, and T7 and the storage capacitor Cst. The thin-film transistors T1, T2, T3, T4, T5, T6, and T7 and the storage capacitor Cst may be connected to signal lines SL1, SL2, SLp, SLn, EL, and DL, an initialization voltage line VIL, and the driving voltage line PL. In an embodiment, at least one of the signal lines SL1, SL2, SLp, SLn, EL, and DL, the initialization voltage line VIL, and/or the driving voltage line PL may be shared by the pixels P adjacent to each other.

The thin-film transistors may include a driving thin-film transistor T1, a switching thin-film transistor T2, a compensation thin-film transistor T3, a first initialization thin-film transistor T4, an operation control thin-film transistor T5, an emission control thin-film transistor T6, and a second initialization thin-film transistor T7.

Some of the plurality of thin-film transistors T1, T2, T3, T4, T5, T6, and T7 may be n-channel metal-oxide semiconductor (“NMOS”) field-effect transistors (n-channel “MOSFETs”), and the rest may be p-channel metal-oxide semiconductor (“PMOS”) field-effect transistors (p-channel MOSFETs).

As an example, as shown in FIG. 4, among the plurality of thin-film transistors T1, T2, T3, T4, T5, T6, and T7, the compensation thin-film transistor T3 and the first initialization thin-film transistor T4 may be n-channel MOSFETs(NMOS), and the rest of the thin-film transistors may be p-channel MOSFETs(PMOS).

In an embodiment, among the plurality of thin-film transistors T1, T2, T3, T4, T5, T6, and T7, the compensation thin-film transistor T3, the first initialization thin-film transistor T4, and the second initialization thin-film transistor T7 may be n-channel MOSFETS(NMOS), and the rest of the thin-film transistors may be p-channel MOSFETs(PMOS). Alternatively, only one of the plurality of thin-film transistors T1, T2, T3, T4, T5, T6, and T7 may be an n-channel MOSFET(NMOS) and the rest of the thin-film transistors may be p-channel MOSFETs(PMOS). Alternatively, all of the plurality of thin-film transistors T1, T2, T3, T4, T5, T6, and T7 may be n-channel MOSFETs(NMOS).

The signal lines may include the first scan line SL1, the second scan line SL2, the previous scan line SLp, the emission control line EL, the next scan line SLn, and the data line DL, where the first scan line SL1 is configured to transfer a first scan signal Sn, the second scan line SL2 is configured to transfer a second scan signal Sn′, the previous scan line SLp is configured to transfer a previous scan signal Sn-1 to the first initialization thin-film transistor T4, the emission control line EL is configured to transfer an emission control signal En to the operation control thin-film transistor T5 and the emission control thin-film transistor T6, the next scan line SLn is configured to transfer a next scan signal Sn+1 to the second initialization thin-film transistor T7, and the data line DL crosses the first scan line SL1 and is configured to transfer a data signal Dm.

The driving voltage line PL may be configured to transfer the driving voltage ELVDD to the driving thin-film transistor T1, and the initialization voltage line VIL may be configured to transfer an initialization voltage Vint initializing the driving thin-film transistor T1 and a pixel electrode.

A driving gate electrode of the driving thin-film transistor T1 may be connected to the storage capacitor Cst, a driving source region of the driving thin-film transistor T1 may be connected to the driving voltage line PL through the operation control thin-film transistor T5, and a driving drain region of the driving thin-film transistor T1 may be electrically connected to a pixel electrode of the organic light-emitting diode OLED through the emission control thin-film transistor T6. The driving thin-film transistor T1 may be configured to receive a data signal Dm and supply a driving current I_{OLED} to the organic light-emitting diode OLED according to a switching operation of the switching thin-film transistor T2.

A switching gate electrode of the switching thin-film transistor T2 is connected to the first scan line SL1, a switching source region of the switching thin-film transistor T2 is connected to the data line DL, and a switching drain region of the switching thin-film transistor T2 is connected to the driving source region of the driving thin-film transistor T1 and connected to the driving voltage line PL through the operation control thin-film transistor T5. The switching thin-film transistor T2 may be turned on according to a first scan signal Sn transferred through the first scan line SL1 and may perform a switching operation of transferring a data signal Dm to the driving source region of the driving thin-film transistor T1, where the data signal Dm is transferred through the data line DL.

A compensation gate electrode of the compensation thin-film transistor T3 is connected to the second scan line SL2. A compensation drain region of the compensation thin-film transistor T3 is connected to the driving drain region of the driving thin-film transistor T1 and connected to the pixel electrode of the organic light-emitting diode OLED through the emission control thin-film transistor T6. A compensation source region of the compensation thin-film transistor T3 is connected to a first electrode CE1 of the storage capacitor Cst and the driving gate electrode of the driving thin-film transistor T1. In addition, the compensation source region is connected to a first initialization drain region of the first initialization thin-film transistor T4.

The compensation thin-film transistor T3 is turned on according to a second scan signal Sn′ and may diode-connect the driving thin-film transistor T1 by electrically connecting the driving gate electrode to the driving drain region of the driving thin-film transistor T1, where the second scan signal Sn′ is transferred through the second scan line SL2.

A first initialization gate electrode of the first initialization transistor T4 is connected to the previous scan line SLp. A first initialization source region of the first initialization thin-film transistor T4 is connected to a second initialization source region of the second initialization thin-film transistor T7 and the initialization voltage line VIL. A first initialization drain region of the first initialization thin-film transistor T4 is connected to the first electrode CE1 of the storage capacitor Cst, the compensation source region of the compensation thin-film transistor T3, and the driving gate electrode of the driving thin-film transistor T1. That is, the first initialization thin-film transistor T4 may be turned on according to a previous scan signal Sn-1 received through the previous scan line SLp and may perform an initialization operation of initializing the voltage of the driving gate electrode of the driving thin-film transistor T1 by transferring the initialization voltage Vint to the driving gate electrode of the driving thin-film transistor T1.

An operation control gate electrode of the operation control thin-film transistor T5 is connected to the emission control line EL, an operation control source region of the operation control thin-film transistor T5 is connected to the driving voltage line PL, and an operation control drain region of the operation control thin-film transistor T5 is connected to the driving source region of the driving thin-film transistor T1 and the switching drain region of the switching thin-film transistor T2.

An emission control gate electrode of the emission control thin-film transistor T6 is connected to the emission control line EL, an emission control source region of the emission control thin-film transistor T6 is connected to the driving drain region of the driving thin-film transistor T1 and the compensation drain region of the compensation thin-film transistor T3, and an emission control drain region of the emission control thin-film transistor T6 is electrically connected to a second initialization drain region of the second initialization thin-film transistor T7 and the pixel electrode of the organic light-emitting diode OLED.

The operation control thin-film transistor T5 and the emission control thin-film transistor T6 may be simultaneously turned on according to an emission control signal En transferred through the emission control line EL, the driving voltage ELVDD is transferred to the organic light-emitting diode OLED, and the driving current I_{OLED} flows through the organic light-emitting diode OLED.

A second initialization gate electrode of the second initialization thin-film transistor T7 is connected to the next scan line SLn, a second initialization drain region of the second initialization thin-film transistor T7 is connected to the emission control drain region of the emission control thin-film transistor T6 and the pixel electrode of the organic light-emitting diode OLED, and a second initialization source region of the second initialization thin-film transistor T7 is connected to the first initialization source region of the first initialization thin-film transistor T4 and the initialization voltage line VIL. The second thin-film transistor T7 is turned on according to a next scan signal Sn+1 transferred through the next scan line SLn and initializes the pixel electrode of the organic light-emitting diode OLED.

As shown in FIG. 4, the second initialization thin-film transistor T7 may be connected to the next scan line SLn. In an embodiment, the second initialization thin-film transistor T7 may be connected to the emission control line EL and driven according to an emission control signal En. The positions of source regions and drain regions may be exchanged depending on the type (a p-type or an n-type) of the transistor.

The storage capacitor Cst may include the first electrode CE1 and a second electrode CE2. The first electrode CE1 of the storage capacitor Cst is connected to the driving gate electrode of the driving thin-film transistor T1, and the second electrode CE2 of the storage capacitor Cst is connected to the driving voltage line PL. The storage capacitor Cst may be configured to store charge corresponding to a difference between a voltage of the driving gate of the driving thin-film transistor T1 and the driving voltage ELVDD.

A specific operation of each pixel P according to an embodiment is described below.

When a previous scan signal Sn-1 is supplied through the previous scan line SLp during an initialization period, the first initialization thin-film transistor T4 is turned on according to the previous scan signal Sn-1, and the driving thin-film transistor T1 may be initialized by the initialization voltage Vint supplied from the initialization voltage line VIL.

When a first scan signal Sn and a second scan signal Sn′ are supplied through the first scan line SL1 and the second scan line SL2 during a data programming period, the switching thin-film transistor T2 and the compensation thin-film transistor T3 are turned on according to the first scan signal Sn and the second scan signal Sn′. In this case, the driving thin-film transistor T1 is diode-connected and forward-biased by the compensation thin-film transistor T3 that is turned on.

Then, a compensation voltage Dm+Vth (Vth has a −value) is applied to the driving gate electrode of the driving thin-film transistor T1, where the compensation voltage Dm+Vth is a voltage reduced by a threshold voltage Vth of the driving thin-film transistor T1 from a data signal Dm supplied from the data line DL.

The driving voltage ELVDD and the compensation voltage Dm+Vth are respectively applied to two opposite ends of the storage capacitor Cst, and charge corresponding to a difference between voltages of the two opposite ends is stored in the storage capacitor Cst.

During an emission period, the operation control thin-film transistor T5 and the emission control thin-film transistor T6 are turned on according to an emission control signal En supplied from the emission control line EL. The driving current I_{OLED} corresponding to a voltage difference between the driving gate voltage of the driving thin-film transistor T1 and the driving voltage ELVDD occurs, and the driving current I_{OLED} is supplied to the organic light-emitting diode OLED through the emission control thin-film transistor T6.

In an embodiment, at least one of the plurality of thin-film transistors T1, T2, T3, T4, T5, T6, and T7 may include a semiconductor layer including an oxide semiconductor, and the rest may include a semiconductor layer including a silicon semiconductor.

Specifically, the driving thin-film transistor T1 directly influencing the brightness of the display apparatus may be configured to include a semiconductor layer including polycrystalline silicon having high reliability, and thus, a high-resolution display apparatus may be implemented through this configuration.

Because an oxide semiconductor has high carrier mobility and a low leakage current, a voltage drop is not large even when a driving time is long. That is, because a color change of an image according to a voltage drop is not large even while the display apparatus is driven in low frequencies, the display apparatus may be driven in low frequencies.

Because the oxide semiconductor has an advantage of a low leakage current, at least one of the compensation thin-film transistor T3, the first initialization thin-film transistor T4, and the second initialization thin-film transistor T7 connected to the driving gate electrode of the driving thin-film transistor T1 may include an oxide semiconductor, and thus, a leakage current that may flow to the driving gate electrode may be prevented, and simultaneously, power consumption may be reduced.

In an embodiment, the driving thin-film transistor T1, the switching thin-film transistor T2, the operation control thin-film transistor T5, the emission control thin-film transistor T6, and the second initialization thin-film transistor 17 may include a semiconductor layer including a silicon semiconductor, and the compensation thin-film transistor T3 and the first initialization thin-film transistor T4 may include a semiconductor layer including an oxide semiconductor. However, the embodiment is not limited thereto.

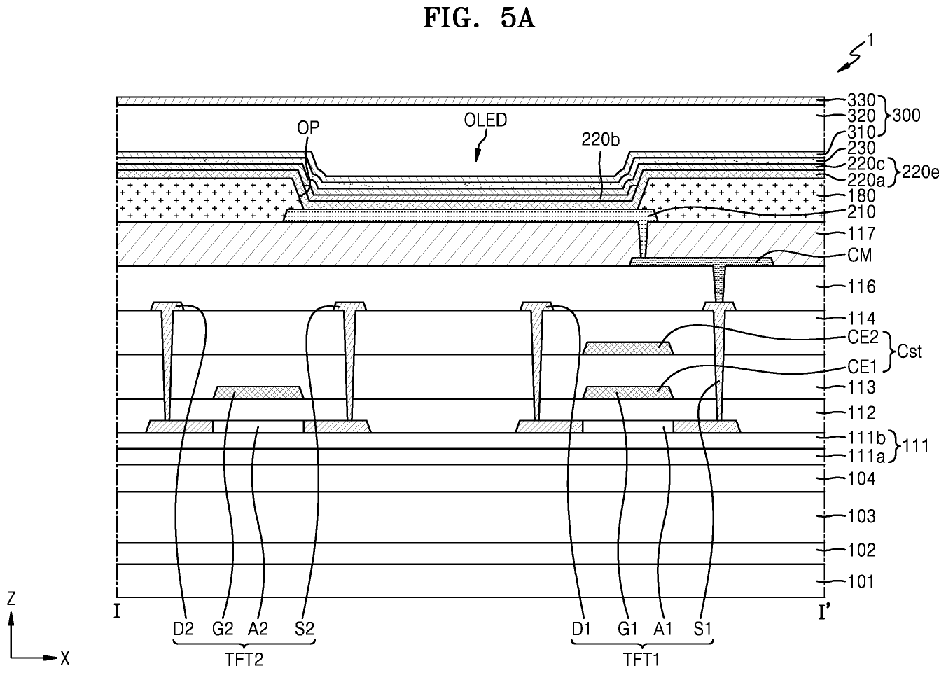

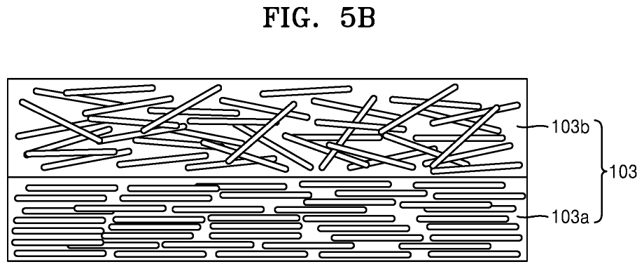

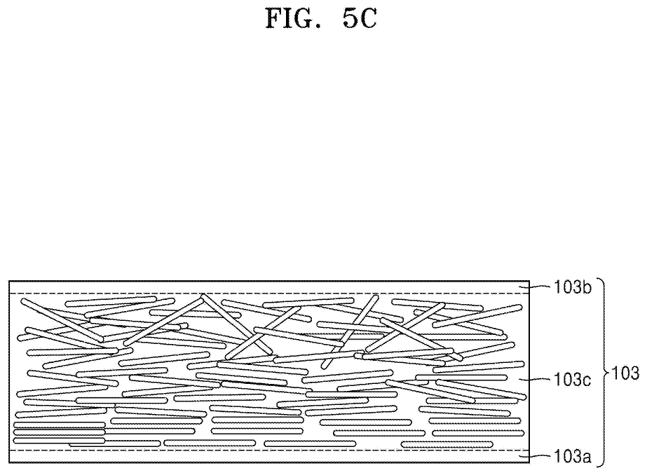

FIGS. 5A to 5C are schematic cross-sectional views of the display apparatus 1 according to an embodiment. Specifically, FIG. 5A is a schematic cross-sectional view of the display apparatus 1 according to an embodiment, taken along line I-I′ of FIG. 1. FIG. 5B is a schematic enlarged cross-sectional view of a second base layer 103 of FIG. 5A. FIG. 5C is a schematic enlarged cross-sectional view of a second base layer 103 of FIG. 5A according to anther embodiment. FIG. 5C will be explained later. Hereinafter, a stack structure of the display apparatus 1 is briefly described with reference to FIGS. 5A and 5B.

Referring to FIG. 5A, a first barrier layer 102 may be disposed on the first base layer 101. The first base layer 101 may include polymer resin or a glass material. The first base layer 101 including the polymer resin may be flexible, rollable, or bendable. In an embodiment, the first base layer 101 may include polyethersulfone, polyacrylate, polyetherimide, polyethylene naphthalate, polyethylene terephthalate, polyphenylene sulfide, polyarylate, polycarbonate, cellulose acetate propionate, or the like. In an embodiment, the first base layer 101 may include polyimide. As an example, the first base layer 101 may include transparent polyimide.

The first barrier layer 102 may be disposed on the first base layer 101. The first barrier layer 102 may include an inorganic insulating material such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO).

The second base layer 103 may be disposed on the first barrier layer 102. In an embodiment, the second base layer 103 may include the same material as a material of the first base layer 101. As an example, the second base layer 103 may include polyimide.

Referring to FIG. 5B, the second base layer 103 may include a first auxiliary base layer 103a and a second auxiliary base layer 103b. The second auxiliary base layer 103b may be disposed on the first auxiliary base layer 103a. The first auxiliary base layer 103a (specifically, materials constituting the first auxiliary base layer 103a) may have a first density, and the second auxiliary base layer 103b (specifically, materials constituting the second auxiliary base layer 103b) may have a second density. The first density may be greater than the second density. The second auxiliary base layer 103b may have the second density less than the first density of the first auxiliary base layer 103a. In other words, the first density of the first auxiliary base layer 103a may be greater than the second density of the second auxiliary base layer 103b.

In an embodiment, polyimide (“PI”) of the first auxiliary base layer 103a may be arranged in a preset orientation (e.g., orientation in the same direction for all PI). In addition, polyimide (PI) of the second auxiliary base layer 103b may be arranged in an arbitrary orientation (e.g., orientations of PIs of the second auxiliary base layer 103b are different). Because PI of the first auxiliary base layer 103a may be arranged in a preset orientation, the material of the first auxiliary base layer 103a may have the first density greater than the second density of the material of the second auxiliary base layer 103b. Because PI of the second auxiliary base layer 103b may be arranged in an arbitrary orientation, the second auxiliary base layer 103b may have the second density less than the first density of the first auxiliary base layer 103a.

In the case where the density of a material of an arbitrary layer is high, the degree in which the arbitrary layer expands when heat is applied thereto may be small. In other words, when the density of a material of an arbitrary layer is high, a thermal expansion coefficient may be small. On the contrary, when the density of a material of an arbitrary layer is low, the degree in which the arbitrary layer expands when heat is applied thereto may be large. In other words, when the density of a material of an arbitrary layer is low, a thermal expansion coefficient may be large.

In an embodiment, the first auxiliary base layer 103a may have the first density greater than the second density of the second auxiliary base layer 103b. The second auxiliary base layer 103b may have the second density less than the first density of the first auxiliary base layer 103a. In other words, the first density of the first auxiliary base layer 103a may be greater than the second density of the second auxiliary base layer 103b. When heat is applied to the first auxiliary base layer 103a and the second auxiliary base layer 103b, the degree in which the second auxiliary base layer 103b having a relatively low density expands may be greater than the degree in which the first auxiliary base layer 103a having a relatively high density expands. The first auxiliary base layer 103a may have a first coefficient of thermal expansion (“CTE”). The second auxiliary base layer 103b may have a second CTE. The second CTE of the second auxiliary base layer 103b may be greater than the first CTE of the first auxiliary base layer 103a. The densities of the first auxiliary base layer 103a and the second auxiliary base layer 103b may be determined through the first CTE of the first auxiliary base layer 103a and the second CTE of the second auxiliary base layer 103b.

In the related art, when a voltage is applied to a display apparatus, due to alignment of dipoles of polyimide (PI) in a second base substrate, a second base layer has a polarity, and an induced electric field is generated. The characteristics of an element change due to the induced electric field generated by the alignment of dipoles of PI of the second base layer, and an afterimage occurs due to a difference in brightness of the display apparatus.

To prevent the afterimage occurring in the display apparatus, a conductive layer is introduced on the second base layer to prevent the induced electric field generated due to the alignment of dipoles of PI of the second base layer, from influencing a semiconductor layer disposed on the second base layer. However, there is inconvenience due to an additional process. In addition, the second base layer is made thick to prevent the induced electric field generated due to the alignment of dipoles of PI of the second base layer, from influencing a semiconductor layer disposed on the second base layer. However, there is inconvenience due to an additional process.

According to an embodiment, by adjusting the densities of the first auxiliary base layer 103a and the second auxiliary base layer 103b of the second base layer 103, and the orientation of a PI chain, the induced electric field generated due to the alignment of dipoles of PI of the second base layer 103 may be prevented from influencing semiconductor layer A1 and A2. Specifically, the PI chain of the first auxiliary base layer 103a may be arranged in a preset orientation. In other words, the PI of the first auxiliary base layer 103a may be arranged in a preset orientation. Specifically, a PI chain of the second auxiliary base layer 103b may be arranged in an arbitrary orientation. In other words, the PI of the second auxiliary base layer 103b may be arranged in an arbitrary orientation. Because the PI of the first auxiliary base layer 103a is arranged in a preset orientation, the first auxiliary base layer 103a may have the first density that is relatively greater than the second density of the second auxiliary base layer 103b. Because the PI of the second auxiliary base layer 103b is arranged in an arbitrary orientation, the second auxiliary base layer 103b may have the second density that is relatively less than the first density of the first auxiliary base layer 103a.

In the case where the PI of the second auxiliary base layer 103b is arranged in a preset orientation and thus the density of the second auxiliary base layer 103b is relatively greater than the density of the case where the PI of the second auxiliary base layer 103b is arranged in an arbitrary orientation, an environment in which dipoles of PI may be aligned in one orientation may be provided. In other words, in the case where the PI of the second auxiliary base layer 103b is arranged in a preset orientation and thus the density of the second auxiliary base layer 103b is relatively greater than the density of the case where the PI of the second auxiliary base layer 103b is arranged in an arbitrary orientation, an environment in which an induced electric field may be generated due to alignment of dipoles of PI may be provided.

According to an embodiment, in the case where PI is disposed in an arbitrary orientation on the first auxiliary base layer 103a, and the second auxiliary base layer 103b having a lower density than the density of the first auxiliary base layer 103a is disposed, dipoles of PI of the second auxiliary base layer 103b may not be aligned in one orientation. In other words, in the case where PI is disposed in an arbitrary orientation on the first auxiliary base layer 103a, and the second auxiliary base layer 103b having a lower density than the density of the first auxiliary base layer 103a is disposed, an induced electric field due to the dipoles of PI of the second auxiliary base layer 103b may not be generated.

Even though the PI of the first auxiliary base layer 103a disposed under the second auxiliary base layer 103b is arranged in a preset orientation and an induced electric field is generated due to alignment of dipoles of the first auxiliary base layer 103a, because the PI of the second auxiliary base layer 103b is arranged in an arbitrary orientation and an induced electric field is not generated due to the arbitrary orientation, the induced electric field of the first auxiliary base layer 103a may not be transferred to the semiconductor layers A1 and A2 above the second auxiliary base layer 103b. In other words, even though the induced electric field is generated due to alignment of dipoles of PI in the first auxiliary base layer 103a, because no electric field is generated due to the arbitrary alignment of dipoles of PI in the second auxiliary base layer 103b disposed on the first auxiliary base layer 103a, the second base layer 103 may not influence the semiconductor layers A1 and A2 due to the induced electric field by the first auxiliary base layer 103a.

A second barrier layer 104 may be disposed on the second base layer 103. In an embodiment, the first barrier layer 102 may include the same material as a material of the second barrier layer 104. In another embodiment, the second barrier layer 104 may include a material different from a material of the first barrier layer 102.

The first barrier layer 102 may be disposed on the first base layer 101 to prevent or reduce a damage to a thin-film transistor due to penetration of foreign substance, moisture, or external air from below the first base layer 101. In addition, the second barrier layer 104 may be disposed over the second base layer 103 to prevent or reduce a damage to a thin-film transistor due to penetration of foreign substance, moisture, or external air from below the first base layer 101.

A buffer layer 111 may be disposed on the second barrier layer 104. The buffer layer 111 may include a first buffer layer 111a and a second buffer layer 111b.

The buffer layer 111 may be disposed on the first base layer 101 and the second base layer 103, may reduce or block penetration of foreign substance, moisture, or external air from below the first base layer 101 and the second base layer 103, and provide a flat surface on the first base layer 101 and the second base layer 103.

The buffer layer 111 may include an inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). Specifically, the first buffer layer 111a may include silicon nitride (SiNₓ). In addition, the second buffer layer 111b may include silicon oxide (SiOₓ). However, the embodiment is not limited thereto.

A first thin-film transistor TFT1 may be disposed on the buffer layer 111, where the first thin-film transistor TFT1 includes the first semiconductor layer A1, a first gate electrode G1, a first source electrode S1, and a first drain electrode D1. In an embodiment, the first semiconductor layer A1 may include a silicon semiconductor. As an example, the first semiconductor layer A1 may include amorphous silicon (a-Si) or low-temperature polycrystalline silicon (“LTPS”) formed by crystallizing a-Si. However, the embodiment is not limited thereto. The first semiconductor layer A1 may include an oxide semiconductor.

A first insulating layer 112 may be disposed on the first semiconductor layer A1. The first insulating layer 112 may include an inorganic material including oxide or nitride. In an embodiment, the first insulating layer 112 may include at least one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO).

The first gate electrode G1 may be disposed on the first insulating layer 112. The first gate electrode G1 may include at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and include a single layer or a multi-layer including the above metals. The first gate electrode G1 may be connected to a gate line configured to apply electrical signals to the first gate electrode G1.

A second insulating layer 113 may be disposed on the first gate electrode G1. The second insulating layer 113 may include at least one inorganic insulating material among silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO). The second insulating layer 113 may include a single layer or a multi-layer including the inorganic insulating material.

The storage capacitor Cst may be disposed on the first insulating layer 112. The storage capacitor Cst may include the first electrode CE1 and the second electrode CE2. The first electrode CE1 of the storage capacitor Cst may overlap the second electrode CE2 with the second insulating layer 113 therebetween.

In an embodiment, the first electrode CE1 of the storage capacitor Cst may overlap the first gate electrode G1 of the first thin-film transistor TFT1. The first electrode CE1 of the storage capacitor Cst may be integrally provided with the first gate electrode G1 of the first thin-film transistor TFT1. In an embodiment, the first electrode CE1 of the storage capacitor Cst may be apart from the first gate electrode G1 of the first thin-film transistor TFT1 and be disposed on the first insulating layer 112 as a separate element. In this case, the first electrode CE1 of the storage capacitor Cst may include the same material as a material of the first gate electrode G1.

The second electrode CE2 of the storage capacitor Cst may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

A third insulating layer 114 may be disposed on the second electrode CE2 of the storage capacitor Cst. The third insulating layer 114 may include at least one inorganic insulating material among silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO). The third insulating layer 114 may include a single layer or a multi-layer including the inorganic insulating material.

A second thin-film transistor TFT2 may be disposed on the buffer layer 111, where the second thin-film transistor TFT2 includes the second semiconductor layer A2, a second gate electrode G2, a second source electrode S2, and a second drain electrode D2. In an embodiment, the second semiconductor layer A2 may include a silicon semiconductor. As an example, the first semiconductor layer A1 may include amorphous silicon (a-Si) or low-temperature polycrystalline silicon (LTPS) formed by crystallizing a-Si. However, the embodiment is not limited thereto. The second semiconductor layer A2 may include an oxide semiconductor.

The first insulating layer 112 may be disposed on the second semiconductor layer A2. The first insulating layer 112 may include an inorganic material including oxide or nitride. The second gate electrode G2 may be disposed on the first insulating layer 112. The second gate electrode G2 and the first gate electrode G1 may be disposed on the same layer. The second gate electrode G2 may include the same material as a material of the first gate electrode G1. The second gate electrode G2 may include at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and include a single layer or a multi-layer including the above metals. The second gate electrode G2 may be connected to a gate line configured to apply electrical signals to the second gate electrode G2.

The second insulating layer 113 may be disposed on the second gate electrode G2. The third insulating layer 114 may be disposed on the second insulating layer 113 and the second electrode CE2 of the storage capacitor Cst.

The first source electrode S1, the first drain electrode D1, the second source electrode S2, and the second drain electrode D2 may be disposed on the third insulating layer 114. The first source electrode S1, the first drain electrode D1, the second source electrode S2, and the second drain electrode D2 may each include a conductive material including molybdenum (Mo), aluminum (Al), copper (Cu), titanium (Ti), and the like, and include a multi-layer or a single layer including the above materials. The first source electrode S1, the first drain electrode D1, the second source electrode S2, and the second drain electrode D2 may each have a multi-layered structure of Ti/Al/Ti.

A first planarization layer 116 may be disposed on the first source electrode S1, the first drain electrode D1, the second source electrode S2, and the second drain electrode D2. The first planarization layer 116 may include a single layer or a multi-layer including an organic material or an inorganic material. In an embodiment, the first planarization layer 116 may include a general-purpose polymer such as benzocyclobutene (“BCB”), polyimide, hexamethyldisiloxane (“HMDSO”), polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. The first planarization layer 116 may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO). After the first planarization layer 116 is formed, chemical mechanical polishing may be performed to provide a flat upper surface.

A connection electrode CM may be disposed on the first planarization layer 116. The connection electrode CM may be electrically connected to the first source electrode S1 or the first drain electrode D1 through a contact hole defined in the first planarization layer 116.

A second planarization layer 117 may be disposed on the connection electrode CM. In an embodiment, the second planarization layer 117 may include the same material as a material of the first planarization layer 116. Alternatively, the second planarization layer 117 may include a material different from a material of the first planarization layer 116.

The organic light-emitting diode OLED may be disposed on the second planarization layer 117, where the organic light-emitting diode OLED includes a pixel electrode 210, an emission layer 220b, and an opposite electrode 230. The pixel electrode 210 may be disposed on the second planarization layer 117. The pixel electrode 210 may be a (semi) light-transmissive electrode or a reflective electrode. The pixel electrode 210 may include a reflective layer and a transparent or semi-transparent electrode layer formed on the reflective layer, where the reflective layer includes at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), and a compound thereof. The transparent or semi-transparent electrode layer may include at least one of indium tin oxide (“ITO”), indium zinc oxide (“IZO”), zinc oxide (ZnO), indium oxide (In₂O₃), indium gallium oxide (“IGO”), and aluminum zinc oxide (“AZO”). The pixel electrode 210 may have a stack structure of ITO/Ag/ITO.

A pixel-defining layer 180 may be disposed on the second planarization layer 117 and may include an opening OP exposing at least a portion of the pixel electrode 210. A region exposed by the opening OP of the pixel-defining layer 180 may be defined as an emission area. The periphery of the emission area is a non-emission area, and the non-emission area may surround the emission area. That is, the display area DA may include the plurality of emission areas and the non-emission area surrounding the plurality of emission areas. The pixel-defining layer 180 may prevent arcs and the like from occurring at the edges of the pixel electrode 210 by increasing a distance between the pixel electrode 210 and the opposite electrode 230 over the pixel electrode 210. The pixel-defining layer 180 may include an organic insulating material such as polyimide, polyamide, acrylic resin, benzocyclobutene, hexamethyldisiloxane, and phenolic resin and be formed by spin coating and the like. In an embodiment, a spacer (not shown) may be further disposed on the pixel-defining layer 180.

An intermediate layer may be disposed on at least a portion of the pixel electrode 210 exposed by the pixel-defining layer 180. The intermediate layer may include the emission layer 220b. A first functional layer 220a and a second functional layer 220c may be selectively disposed under and on the emission layer 220b.

In an embodiment, the first functional layer 220a may be disposed under the emission layer 220b, and the second functional layer 220c may be disposed on the emission layer 220b. The first functional layer 220a and the second functional layer 220c disposed under and on the emission layer 220b may be collectively referred to as organic functional layers 220e.

The first functional layer 220a may include a hole injection layer (“HIL”) and/or a hole transport layer (“HTL”), and the second functional layer 220c may include an electron transport layer (“ETL”) and/or an electron injection layer (“EIL”).

The emission layer 220b may include an organic material including a fluorescent or phosphorous material emitting red, green, blue, or white light. The emission layer 220b may include a low-molecular weight organic material or a polymer organic material.

In the case where the emission layer 220b includes a low molecular weight organic material, the intermediate layer may have a structure in which a hole injection layer, a hole transport layer, an emission layer 220b, an electron transport layer, an electron injection layer, and the like are stacked in a single or composite configuration. The intermediate layer 220 may include, as a low molecular weight organic material, various organic materials such as copper phthalocyanine (CuPc), N, N′-Di (naphthalene-1-yl)-N, N′-diphenyl-benzidine (“NPB”), and tris-8-hydroxyquinoline aluminum (Alq3).

In the case where the emission layer 220b include a polymer organic material, the intermediate layer may generally have a structure including the hole transport layer and the emission layer 220b. In this case, the HTL may include poly (3, 4-ethylenedioxythiophene) (“PEDOT”), and the emission layer may include a polymer material such as a polyphenylene vinylene (“PPV”)-based material and a polyfluorene-based material. The emission layer 220b may be formed by screen printing, inkjet printing, laser induced thermal imaging (“LITI”), or the like.

The opposite electrode 230 may be disposed on the intermediate layer. The opposite electrode 230 is disposed on the intermediate layer and may be disposed to cover the intermediate layer entirely. The opposite electrode 230 is arranged in the display area DA and may be arranged to cover the display area DA entirely. That is, the opposite electrode 230 may be formed as one body over the display panel DP entirely to cover the pixels P arranged in the display area DA by using an open mask.

The opposite electrode 230 may include a conductive material having a low work function. As an example, the opposite electrode 230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. Alternatively, the opposite electrode 230 may further include a layer on the (semi) transparent layer, the layer including ITO, IZO, ZnO, or In₂O₃.

In an embodiment, a thin-film encapsulation layer 300 may be disposed on the organic light-emitting diode OLED. The thin-film encapsulation layer 300 may include at least one inorganic layer and at least one organic layer. In an embodiment, the thin-film encapsulation layer 300 may include a first inorganic layer 310, an organic layer 320, and a second inorganic layer 330 that are sequentially stacked.

The first inorganic layer 310 and the second inorganic layer 330 may include at least one inorganic insulating material among silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO). The organic layer 320 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane, an acryl-based resin (e.g., polymethylmethacrylate, poly acrylic acid, and the like), or an arbitrary combination thereof.

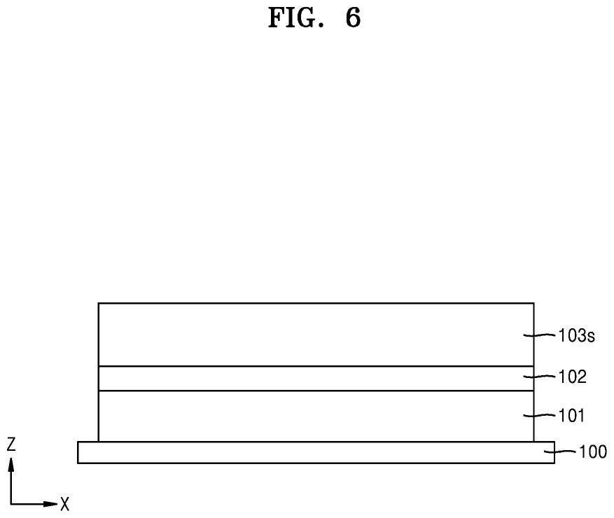

FIGS. 6 to 8 are schematic cross-sectional views showing a method of manufacturing the display apparatus 1 according to an embodiment.

Referring to FIGS. 6 to 8, a method of manufacturing the display apparatus 1 may include: forming the first base layer 101 and the first barrier layer 102 on a carrier substrate 100; coating a material 103s for forming the second base layer on the first barrier layer 102, where the material 103s for forming the second base layer includes polyacrylic acid (“PAA”) and a solvent; drying (500) the solvent of the material 103s for forming the second base layer; a first curing operation (501) of curing a surface 103s1 of the material 103s for forming the second base layer; and a second curing operation (502) of curing the material 103s to form the second base layer 103 including the first auxiliary base layer 103a and the second auxiliary base layer 103b disposed on the first auxiliary base layer 103a, where the drying (500) of the solvent of the material 103s for forming the second base layer and the first curing operation (501) of curing the surface 103s1 of the material 103s for forming the second base layer may be simultaneously performed.

Referring to FIG. 6, the first base layer 101 may be formed on the carrier substrate 100, and the second barrier layer 102 may be formed on the first base layer 101. The first base layer 101 may include polyethersulfone, polyacrylate, polyetherimide, polyethylene naphthalate, polyethylene terephthalate, polyphenylene sulfide, polyarylate, polycarbonate, cellulose acetate propionate, or the like. In an embodiment, the first base layer 101 may include polyimide. The first barrier layer 102 may include an inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The material 103s, for forming the second base layer, including polyacrylic acid (PAA) and the solvent may be coated on the first barrier layer 102. The solvent of the material 103s for forming the second base layer may include methylpyrrolidone (NMP, N-Methyl-2-pyrrolidone).

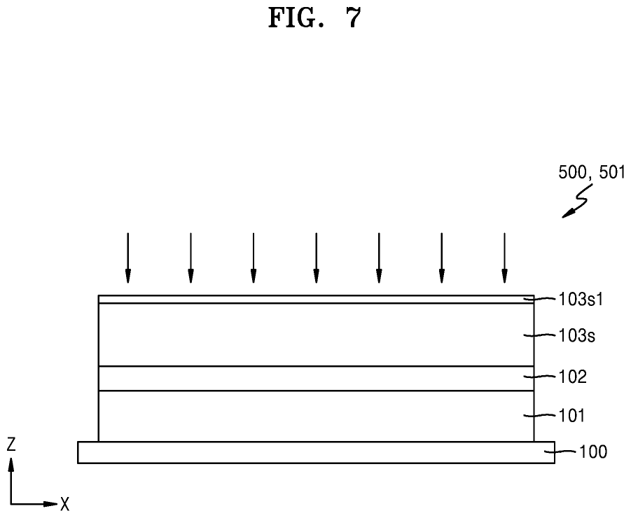

Referring to FIG. 7, the drying (500) of the solvent of the material 103s for forming the second base layer may be performed. Most of the solvent of the material 103s for forming the second base layer may be evaporated through the drying (500) of the solvent of the material 103s for forming the second base layer. In other words, most of methylpyrrolidone (NMP, N-Methyl-2-pyrrolidone) of the material 103s for forming the second base layer may be evaporated through the drying (500) of the solvent of the material 103s for forming the second base layer.

The first curing operation (501) of curing the surface 103s1 of the material 103s for forming the second base layer may be performed simultaneously with the drying (500) of most of the solvent of the material 103s for forming the second base layer. In other words, simultaneously with the drying (500) of most of the solvent of the material 103s for forming the second base layer, the surface 103s1 of the material 103s for forming the second base layer may be cured through the first curing operation (501). Simultaneously with evaporation of most of methylpyrrolidone (NMP, N-Methyl-2-pyrrolidone) of the material 103s for forming the second base layer, the surface 103s1 of the material 103s for forming the second base layer may be cured. A temperatures in the drying (500) of the solvent of the material 103s for forming the second base layer and the first curing operation (501) of curing the surface 103s1 of the material 103s for forming the second base layer may be 50° C. or more and 90° C. or less.

In the drying (500) of the solvent of the material 103s for forming the second base layer, only the surface 103s1 of the material 103s for forming the second base layer may be exposed to the atmosphere. In the drying (500) of the solvent of the material 103s for forming the second base layer, the heat is applied to the material 103s for forming the second base layer. Therefore, curing may be performed from the surface 103s1 of the material 103s for forming the second base layer. In other words, simultaneously with the drying (500) of the solvent of the material 103s for forming the second base layer, the first curing operation (501) of curing the surface 103s1, exposed to the atmosphere, of the material 103s for forming the second base layer may be performed.

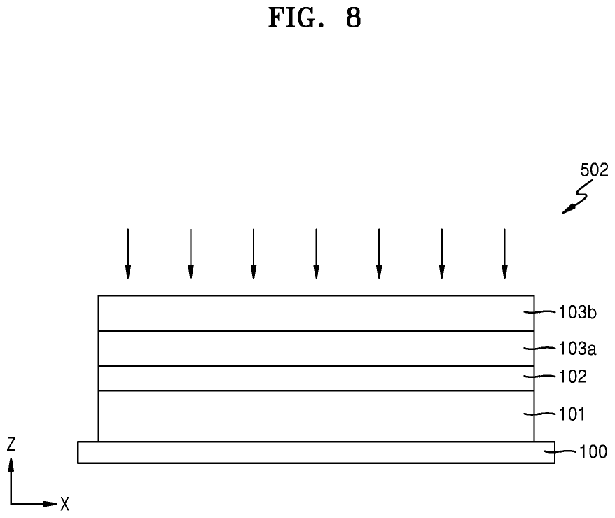

Referring to FIG. 8, the material 103s for forming the second base layer is cured through the second curing operation (502), the second base layer 103 including the first auxiliary base layer 103a and the second auxiliary base layer 103b may be formed. Specifically, among the material 103s for forming the second base layer that passes through the drying (500) of the solvent of the material 103s for forming the second base layer and the first curing operation (501), a portion apart from the surface 103s1 may be cured to form the first auxiliary base layer 103a. In addition, among the material 103s for forming the second base layer that passes through the drying (500) and the first curing operation (501), a portion adjacent to the surface 103s1 may be cured to form the second auxiliary base layer 103b. Through the second curing operation 502, polyacrylic acid (PAA) of the material 103s for forming the second base layer may become PI through an imidization reaction. In other words, PI included in the first auxiliary base layer 103a and the second auxiliary base layer 103b may be formed through the second curing operation (502). A temperature of a process in which the second curing operation of curing the material 103s to form the second base layer 103 including the first auxiliary base layer 103a and the second auxiliary base layer 103b may be 450° C. or more and 470° C. or less. However, the embodiment is not limited thereto.

PI of the first auxiliary base layer 103a formed by curing a portion apart from the surface 103s1 among the material 103s for forming the second base layer may be arranged in a preset orientation. On the contrary, PI of the second auxiliary base layer 103b formed by curing a portion adjacent to the surface 103s1 among the material 103s for forming the second base layer may be arranged in an arbitrary orientation.

The first auxiliary base layer 103a may have the first density. The second auxiliary base layer 103b may have the second density. Because PI of the first auxiliary base layer 103a is arranged in the preset orientation, the first density of the first auxiliary base layer 103a may be greater than the second density of the second auxiliary base layer 103b. On the contrary, because PI of the second auxiliary base layer 103b is arranged in an arbitrary orientation, the second density of the second auxiliary base layer 103b may be less than the first density of the first auxiliary base layer 103a.

The material 103s for forming the second base layer may include polyacrylic acid (PAA) and the solvent. Specifically, the material 103s for forming the second base layer may include polyacrylic acid (PAA) and methylpyrrolidone (NMP, N-Methyl-2-pyrrolidone). Most of the solvent of the material 103s for forming the second base layer may be dried through the drying (500) of the solvent of the material 103s for forming the second base layer. In other words, most of methylpyrrolidone (NMP, N-Methyl-2-pyrrolidone) of the material 103s for forming the second base layer may be dried through the drying (500) of the solvent of the material 103s for forming the second base layer. However, even after the drying (500) of the solvent of the material 103s for forming the second base layer is performed, the solvent that is not evaporated may be left in the material 103s for forming the second base layer. Even after the drying (500) of the solvent of the material 103s for forming the second base layer is performed, methylpyrrolidone (NMP, N-Methyl-2-pyrrolidone) that is not evaporated may be left in the material 103s for forming the second base layer.

When the solvent remains, the imidization reaction of polyacrylic acid (PAA) may be performed rapidly. In other words, when the solvent remains, polyacrylic acid (PAA) is imidized to form PI rapidly. This is because solvent molecules around polyacrylic acid (PAA) increases mobility of carboxyl and amino groups. In other words, methylpyrrolidone (NMP, N-Methyl-2-pyrrolidone) molecules around polyacrylic acid (PAA) increase mobility of carboxyl and amino groups, and when methylpyrrolidone (NMP, N-Methyl-2-pyrrolidone) remains, an imidization speed of polyacrylic acid (PAA) or a speed at which PI is formed may increase. When the imidization reaction of polyacrylic acid (PAA) is performed rapidly, even before the chains of PI are aligned, PI is formed and PI may be arranged in an arbitrary orientation.

For PI of the second auxiliary base layer 103b disposed on the first auxiliary base layer 103a to be arranged in the arbitrary orientation, the amount of solvent remaining when the second auxiliary base layer 103b is formed may be large. In other words, the amount of solvent remaining on a portion adjacent to the surface 103s1 among the material 103s for forming the second base layer may be large.

After the first curing operation (501) of curing the surface 103s1 of the material 103s for forming the second base layer is performed, the second curing operation (502) may be performed. While the second curing operation (502) is performed, the solvent of the material 103s for forming the second base layer may be dried. In other words, while the second curing operation (502) is performed, methylpyrrolidone (NMP, N-Methyl-2-pyrrolidone) of the material 103s for forming the second base layer may be evaporated.

During the first curing operation (501), the surface 103s1 of the material 103s for forming the second base layer may be cured. Because the surface 103s1 of the material 103s for forming the second base layer is cured, evaporation of the solvent included in a portion adjacent to the surface 103s1 among the material 103s for forming the second base layer may be suppressed during the second curing operation (502). In other words, because evaporation of methylpyrrolidone (NMP, N-Methyl-2-pyrrolidone) is suppressed in a portion adjacent to the surface 103s1 among the material 103s for forming the second base layer during the second curing operation (502), a greater amount of methylpyrrolidone (NMP, N-Methyl-2-pyrrolidone) may remain than the portion apart from the surface 103s1.

Because, in a portion adjacent to the surface 103s1 among the material 103s for forming the second base layer, evaporation of the solvent is suppressed due to the curing of the surface 103s1 in the first curing operation, and therefore, the imidization speed of polyacrylic acid (PAA) may be increased. In other words, in a portion adjacent to the surface 103s1 among the material 103s for forming the second base layer, the speed at which PI is formed may increase, and thus, PI may be aligned in an arbitrary orientation. Because PI of the second auxiliary base layer 103b is aligned in an arbitrary orientation, the density of the second auxiliary base layer 103b may be low. In contrast, because the solvent is relatively easily evaporated in a portion apart from the surface 103s1 among the material 103s for forming the second base layer, the imidization speed of polyacrylic acid (PAA) in the portion apart from the surface 103s1 among the material 103s may be relatively slow. Specifically, because, in a portion apart from the surface 103s1 among the material 103s for forming the second base layer, the solvent is evaporated through two lateral surfaces except for the surface 103s1 that is cured among the material 103s for forming the second base layer, the imidization speed of polyacrylic acid (PAA) may be relatively slow. In other words, in a portion apart from the surface 103s1 among the material 103s for forming the second base layer, the speed at which PI is formed may be slow, and thus, PI may be aligned in a preset orientation. Because PI of the first auxiliary base layer 103a is aligned in a preset orientation, the density of the first auxiliary base layer 103a may be high.

The second base layer 103 made by this method of manufacturing the display apparatus 1 may have a structure shown in FIG. 5C. In this structure, orientation of polyimide in the second base layer 103 may be gradually changed from the preset orientation of the first auxiliary base layer 103a to the arbitrary orientation of the second auxiliary base layer 103b in a direction from a bottom surface to a top surface thereof. This structure may be illustrated as the second base layer 103 may further include a third auxiliary base layer 103c between the first auxiliary base layer 103a and second auxiliary base layer 103b, and orientation of the polyimide of the third auxiliary base layer 103c is gradually changed from the preset orientation to the arbitrary orientation in a direction from the first auxiliary base layer 103a to the second auxiliary base layer 103b. In this case, a bottom portion of the second base layer 103 may correspond to the first auxiliary base layer 103a, and a top portion of the second base layer 103 may correspond to the second auxiliary base layer 103b. The density of the third auxiliary base layer 103c may gradually decrease from the bottom surface to the top surface thereof, and the thermal expansion coefficient of the third auxiliary base layer 103c may gradually increase from the bottom surface to the top surface thereof.

Though not shown, the second barrier layer 104 may be disposed on the second base layer 103. The second barrier layer 104 may include the same material as a material of the first barrier layer 102. However, the embodiment is not limited thereto. In another embodiment, the second barrier layer 104 may include a material different from a material of the first barrier layer 102. In addition, after the process is completed, the carrier substrate 100 may be separated.

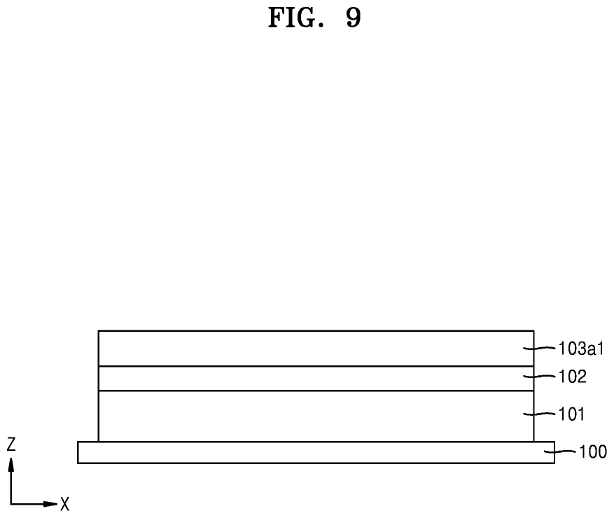

FIGS. 9 to 14 are schematic cross-sectional views showing a method of manufacturing the display apparatus 1 according to an embodiment.

Referring to FIGS. 9 to 14, the method of manufacturing the display apparatus 1 may include: forming the first base layer and the first barrier layer on the carrier substrate; coating a material for forming the first auxiliary base layer on the first barrier layer, where the material for forming the first auxiliary base layer includes polyacrylic acid (PAA) and a first solvent; drying the solvent of the material for forming the first auxiliary base layer; a first auxiliary curing operation of curing the material for forming the first auxiliary base layer to form the first auxiliary base layer; coating a material for forming a second auxiliary base layer on the first auxiliary base layer, where the material for forming the second auxiliary base layer includes polyacrylic acid (PAA) and a second solvent; drying the second solvent of the material for forming the second auxiliary base layer; and a second auxiliary curing operation of curing the material for forming the second auxiliary base layer to form the second auxiliary base layer.

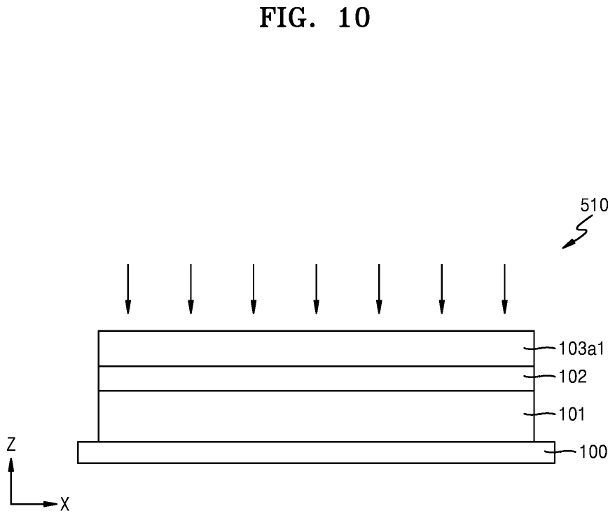

Referring to FIG. 10, the first base layer 101 and the first barrier layer 102 may be formed on the carrier substrate 100. The first base layer 101 may include polyethersulfone, polyacrylate, polyetherimide, polyethylene naphthalate, polyethylene terephthalate, polyphenylene sulfide, polyarylate, polycarbonate, cellulose acetate propionate, or the like. In an embodiment, the first base layer 101 may include polyimide. The first barrier layer 102 may include an inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

A material 103s, for forming the first auxiliary base layer, including polyacrylic acid (PAA) and the first solvent may be coated on the first barrier layer 102. The first solvent of the material 103s for forming the first auxiliary base layer may include methylpyrrolidone (NMP, N-Methyl-2-pyrrolidone).

Referring to FIG. 10, the drying (510) of the first solvent of the material 103s for forming the first auxiliary base layer may be performed. Most of the first solvent of the material 103s for forming the first auxiliary base layer may be evaporated through the drying (510) of the first solvent of the material 103s for forming the first auxiliary base layer. In other words, most of methylpyrrolidone (NMP, N-Methyl-2-pyrrolidone) of the material 103a1 for forming the first auxiliary base layer may be evaporated through the drying (510) of the first solvent of the material 103a1 for forming the first auxiliary base layer. A temperature of the process in which the drying (510) of the first solvent of the material 103s for forming the first auxiliary base layer is performed may be 70° C. or more and 90° C. or less.

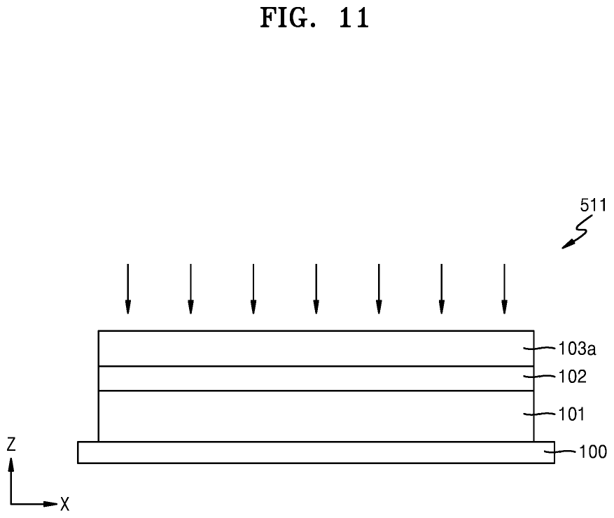

Referring to FIG. 11, the first auxiliary curing operation (511) of curing the material 103a1 to form the first auxiliary base layer 103a may be performed. Through the first auxiliary curing operation, polyacrylic acid of the first auxiliary base layer 103a may be imidized to form polyimide.

A temperature of the process in which the first auxiliary curing operation (511) is performed may be 450° C. or more and 470° C. or less. In the first auxiliary curing operation (511), the temperate of the process may start at about 80° C. The first auxiliary curing operation (511) may have a first auxiliary curing speed. The first auxiliary curing speed may denote the degree in which the temperature rises from the temperature at the start of the first auxiliary curing operation (511) until the temperature reaches the end point. In other words, the first auxiliary curing speed may denote the degree (i.e., how fast) in which the temperature rises from 80° C., which is the temperature at the start of the first auxiliary curing operation, until the temperature reaches about 450° ° C. to about 460° C. The first auxiliary curing speed may be 2 degrees in Celsius per minute (C/min) or more and 3° C./min or less.

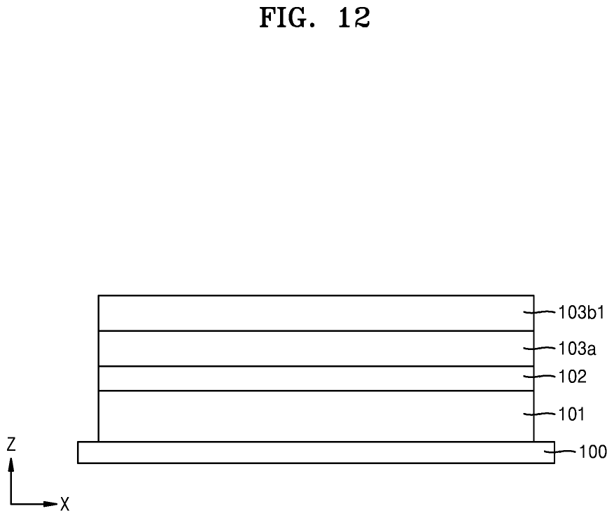

Referring to FIG. 12, the first auxiliary base layer 103a is formed, and then, a material 103b1 for forming a second auxiliary base layer may be coated on the first auxiliary base layer 103a, where the material 103b1 for forming the second auxiliary base layer includes polyacrylic acid (PAA) and a second solvent. The second solvent of the material 103b1 for forming the second auxiliary base layer may include methylpyrrolidone (NMP, N-Methyl-2-pyrrolidone).

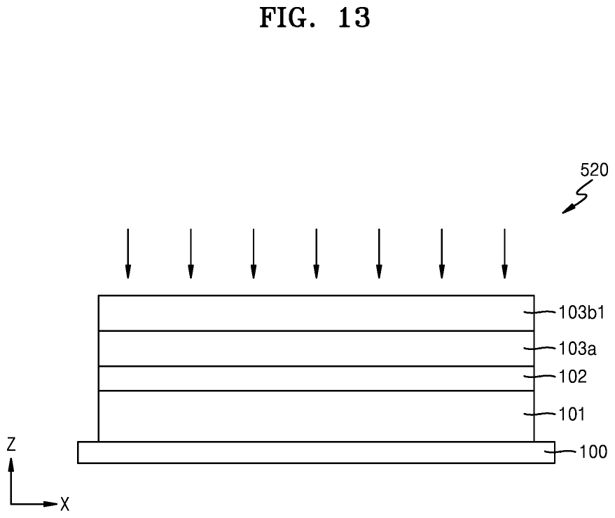

Referring to FIG. 13, the drying (520) of the second solvent of the material 103b1 for forming the second auxiliary base layer may be performed. Most of the second solvent of the material 103b1 for forming the second auxiliary base layer may be evaporated through the drying (520) of the second solvent of the material 103b1 for forming the second auxiliary base layer. In other words, most of methylpyrrolidone (NMP, N-Methyl-2-pyrrolidone) of the material 103b1 for forming the second auxiliary base layer may be evaporated through the drying (520) of the second solvent of the material 103b1 for forming the second auxiliary base layer. A temperature of the process in which the drying (520) of the second solvent of the material 103b1 for forming the second auxiliary base layer is performed may be 30° C. or more and 50° C. or less.

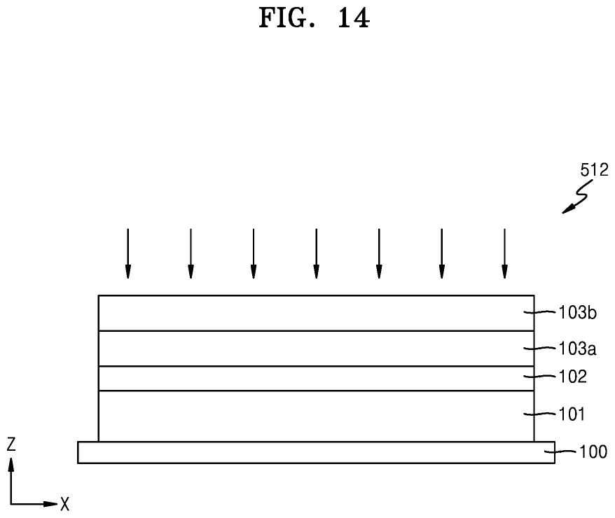

Referring to FIG. 14, the second auxiliary curing operation (512) of curing the material 103b1 to form the second auxiliary base layer 103b may be performed. Through the second auxiliary curing operation (512), polyacrylic acid of the second auxiliary base layer 103b may be imidized to form polyimide.

A temperature of the process in which the second auxiliary curing operation (512) is performed may be 450° C. or more and 470° C. or less. The temperature of a process in which the first auxiliary curing operation (511) is performed may be the same as the temperature of a process in which the second auxiliary curing operation (512) is performed. In the second auxiliary curing operation (512), the temperate of the process may start at about 80° C. The second auxiliary curing operation (512) may have a second auxiliary curing speed. The second auxiliary curing speed may denote the degree (i.e., how fast) in which the temperature rises from the temperature at the start of the second auxiliary curing operation (512) until the temperature reaches the end point. In other words, the second auxiliary curing speed may denote the degree in which the temperature rises from 80° C., which is the temperature at the start of the first auxiliary curing operation, until the temperature reaches about 450° C. to about 470° C. The second auxiliary curing speed may be 4° C./min or more and 5° C./min or less. Although the temperature of the process in which the first auxiliary curing operation (511) is performed may be the same as the temperature of a process in which the second auxiliary curing operation (512) is performed, the first auxiliary curing speed may be different from the second auxiliary curing speed. The second auxiliary curing speed of the second auxiliary curing operation (512) may be greater than the first auxiliary curing speed of the first auxiliary curing operation (511).

Conditions for the drying (510) of the first solvent of the material 103a1 for forming the first auxiliary base layer and the drying (520) of the second solvent of the material 103b1 for forming the second auxiliary base layer may determine the alignment of PI of the first auxiliary base layer 103a and the second auxiliary base layer 103b. Curing conditions for the first auxiliary curing operation (511) of forming the first auxiliary base layer 103a and the second auxiliary curing operation (512) of forming the second auxiliary base layer 103b may determine the alignment of PI of the first auxiliary base layer 103a and the second auxiliary base layer 103b. In the case where the first solvent of the material 103a1 for forming the first auxiliary base layer is dried at the temperature of 70° C. or more and 90° C. or less, the temperature of the first auxiliary curing operation (511) is 450° C. or more and 470° C. or less, and the first auxiliary curing speed is 2° C./min or more and 3° C./min or less, PI of the first auxiliary base layer 103a may be aligned in a preset orientation. In addition, in the case where the second solvent of the material 103b1 for forming the second auxiliary base layer is dried at the temperature of 30° C. or more and 50° C. or less, the temperature of the second auxiliary curing operation (512) is 450° C. or more and 470° C. or less, and the second auxiliary curing speed is 4° C./min or more and 5° C./min or less, PI of the second auxiliary base layer 103b may be aligned in an arbitrary orientation. Because, when the second auxiliary curing speed of the second auxiliary curing operation (512) is greater than the first auxiliary curing speed of the first auxiliary curing operation (511), polyacrylic acid (PAA) in the material 103b1 for forming the second auxiliary base layer is imidized to form polyimide (PI) before PI is aligned, and PI of the second auxiliary base layer 103b may be arranged in an arbitrary orientation. For the same reason, polyacrylic acid (PAA) in the material 103a1 for forming the first auxiliary base layer is slowly imidized to form polyimide (PI) while PI is aligned, and PI of the first auxiliary base layer 103a may be arranged in a preset orientation to have the first density greater than the second density of the second auxiliary base layer 103b. PI of the second auxiliary base layer 103b may be arranged in an arbitrary orientation to have the second density less than the first density of the first auxiliary base layer 103a.

Though not shown, the second barrier layer 104 may be disposed on the second base layer 103. The second barrier layer 104 may include the same material as a material of the first barrier layer 102. However, the embodiment is not limited thereto. In another embodiment, the second barrier layer 104 may include a material different from a material of the first barrier layer 102. In addition, after the process is completed, the carrier substrate 100 may be separated.

In the related art, when a voltage is applied to the display apparatus, an induced electric field due to the alignment of PI dipoles included in a base layer influences a semiconductor layer disposed on the base layer, and thus, a difference in brightness of the display apparatus may occur and an afterimage may occur.

Although the influence of the induced electric field due to PI of the base layer on the semiconductor layer may be reduced by introducing a conductive layer on the base layer or adjusting the thickness of the base layer, time and cost consumed have increased due to an additional process.

In contrast, according to an embodiment, the second base layer 103 adjacent to the thin-film transistor may include the first auxiliary base layer 103a and the second auxiliary base layer 103b disposed on the first auxiliary base layer 103a. PI of the first auxiliary base layer 103a may be arranged in a preset orientation, and PI of the second auxiliary base layer 103b may be arranged in an arbitrary orientation. Due to the arrangement of PI, the density of the first auxiliary base layer 103a may be greater than the density of the second auxiliary base layer 103b. Because PI of the second auxiliary base layer 103b is arranged in an arbitrary orientation, even though a voltage is applied to the display apparatus 1, PI dipoles cannot be aligned and an influence due to the induced electric field may be reduced. Because the first auxiliary base layer 103a and the second auxiliary base layer 103b may be formed with different curing conditions during the process of forming the second base layer 103, an additional process is not required and efficiency in the manufacturing process may be increased.

According to an embodiment having the above configuration, the display apparatus with improved visibility, and the method of manufacturing the display apparatus may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a first base layer including a first auxiliary base layer and a second auxiliary base layer disposed on the first auxiliary base layer; and
a semiconductor layer disposed on the first base layer,
Wherein the first auxiliary base layer has a first density, and the second auxiliary base layer has a second density less than the first density.

2. The display apparatus of claim 1, wherein polyimide of the first auxiliary base layer is arranged in a present orientation, and
polyimide of the second auxiliary base layer is arranged in an arbitrary orientation.

3. The display apparatus of claim 2, wherein the first base layer further comprises a third auxiliary base layer between the first auxiliary base layer and second auxiliary base layer, and
Orientation of polyimide of the third auxiliary base layer is gradually changed from the present orientation to the arbitrary orientation in a direction from the first auxiliary base layer to the second auxiliary base layer.

4. The display apparatus of claim 1, wherein the first auxiliary base layer has a first thermal expansion coefficient, and the second auxiliary base layer has a second thermal expansion coefficient greater than the first thermal expansion coefficient.

5. The display apparatus of claim 1, further comprising:
a first barrier layer disposed under the first base layer;
a second base layer disposed under the first barrier layer;
a second barrier layer disposed on the first base layer; and
a buffer layer disposed on the second barrier layer.

6. A method of manufacturing a display apparatus, the method comprising:
forming a first base layer and a first barrier layer, on a carrier substrate;
coating, on the first barrier layer, a material for forming a second base layer, wherein the material for forming the second base layer includes polyacrylic acid and a solvent;
drying the solvent included in the material for forming the second base layer;
performing first curing of a surface of the material for forming the second base layer; and
performing second curing of the material for forming the second base layer, to form the second base layer including a first auxiliary base layer and a second auxiliary base layer disposed on the first auxiliary base layer,
wherein the drying of the solvent included in the material for forming the second base layer and the first curing of the surface of the material for forming the second base layer are performed simultaneously, the second curing is performed after the first curing and
the first auxiliary base layer has a first density, and the second auxiliary base layer has a second density less than the first density.

7. The method of claim 6, wherein the first auxiliary base layer and the second auxiliary base layer include polyimide,
the polyimide of the first auxiliary base layer is arranged in a preset orientation, and
the polyimide of the second auxiliary base layer is arranged in an arbitrary orientation.

8. The method of claim 6, wherein the second curing of the material for forming the second base layer to form the second base layer including the first auxiliary base layer and the second auxiliary base layer disposed on the first auxiliary base layer includes:
curing a first portion of the material for forming the second base layer, to form the first auxiliary base layer, the first portion being apart from a top surface of the material for forming the second base layer; and
curing a second portion, of the material for forming the second base layer, adjacent to the top surface of the material for forming the second base layer, to form the second auxiliary base layer.

9. The method of claim 6, wherein, in the second curing of the material for forming the second base layer to form the second base layer including the first auxiliary base layer and the second auxiliary base layer disposed on the first auxiliary base layer, polyacrylic acid of the material for forming the second base layer is imidized to form polyimide.

10. The method of claim 6, wherein the solvent includes methylpyrrolidone (NMP, N-methyl-2-pyrrolidone).

11. The method of claim 6, wherein a temperature of a process in which the drying of the solvent included in the material for forming the second base layer and the first curing are performed is at least 50° C. and not more than 90° C.

12. The method of claim 6, wherein a temperature of a process in which the second curing is performed is at least 450° C. and not more than 470° C.

13. A method of manufacturing a display apparatus, the method comprising:
forming a first base layer and a first barrier layer, on a carrier substrate;
coating, on the first barrier layer, a material for forming a first auxiliary base layer, wherein the material for forming the first auxiliary base layer includes polyacrylic acid and a first solvent;
drying the first solvent of the material for forming the first auxiliary base layer;
performing first auxiliary curing of the material for forming the first auxiliary base layer, to form the first auxiliary base layer;
coating, on the first auxiliary base layer, a material for forming a second auxiliary base layer, wherein the material for forming the second auxiliary base layer includes polyacrylic acid and a second solvent;
drying the second solvent of the material for forming the second auxiliary base layer; and
performing second auxiliary curing of the material for forming the second auxiliary base layer, to form the second auxiliary base layer,
wherein a second base layer includes the first auxiliary base layer and the second auxiliary base layer disposed on the first auxiliary base layer,
the first auxiliary base layer has a first density, and the second auxiliary base layer has a second density less than the first density.

14. The method of claim 13, wherein the first auxiliary base layer and the second auxiliary base layer include polyimide,
the polyimide of the first auxiliary base layer is arranged in a preset orientation, and
the polyimide of the second auxiliary base layer is arranged in an arbitrary orientation.

15. The method of claim 13, wherein a temperature of a process in which the drying of the solvent included in the material for forming the first auxiliary base layer is performed is at least 70° C. and not more than 90° C.

16. The method of claim 13, wherein a temperature of a process in which the drying of the solvent included in the material for forming the second auxiliary base layer is performed is at least 30° C. and not more than 50° C.

17. The method of claim 13, wherein the first auxiliary curing of the material has a first auxiliary curing speed, and the second auxiliary curing of the material has a second auxiliary curing speed, and
the second auxiliary curing speed is greater than the first auxiliary curing speed.

18. The method of claim 13, wherein a temperature of a process of the first auxiliary curing of the material and the second auxiliary curing of the material is at least 450° C. and not more than 470° C.

19. The method of claim 13, wherein the first solvent and the second solvent each include methylpyrrolidone (NMP, N-methyl-2-pyrrolidone).

20. The method of claim 13, wherein, in the first auxiliary curing of the material and the second auxiliary curing of the material, polyacrylic acid of the material for forming the first auxiliary base layer and the material for forming the second auxiliary base layer is imidized to form polyimide.
